(19) United States
(12) Patent Application Publication
(10) Pub. No.: US 2026/0231649 A1
(43) Pub. Date: Aug. 6, 2026

(54) DISPLAY DEVICE

(71) Applicant: SK hynix Inc., Icheon-si (KR)

(72) Inventors: Seo Ho LEE, Icheon-si (KR); Ji Na EOM, Icheon-si (KR); Jin Su LIM, Icheon-si (KR); Young Hwan HYEON, Icheon-si (KR)

(21) Appl. No.: 19/249,637

(22) Filed: Jun. 25, 2025

(30) Foreign Application Priority Data
Jan. 31, 2025 (KR) 10-2025-0012165

(51) Int. Cl. H10K 59/80

(52) U.S. Cl. CPC H10K 59/80518; H10K 59/878

(57) ABSTRACT

A display device is provided to include a substrate; a reflective electrode disposed over the substrate and including a first layer, a second layer disposed on the first layer, and a third layer disposed on the second layer; a first electrode disposed over the reflective electrode; a common light-emitting layer disposed over the first electrode; and a second electrode disposed over the common light-emitting layer, wherein the first and second electrodes are structured to supply an electrical signal to the common light-emitting layer to cause emission of light, and wherein the first layer and the third layer of the reflective electrode include a metal, and the second layer of the reflective electrode includes a metal compound.

### CROSS-REFERENCE TO RELATED APPLICATION

This application claims priority to and the benefit of Korean Patent Application No. 10-2025-0012165, filed on Jan. 31, 2025, the disclosure of which is incorporated herein by reference in its entirety.

### TECHNICAL FIELD

Embodiments of the present disclosure relate to a display device.

### BACKGROUND

With development of information and communication industry, the demand for display devices configured to display images is increasing, and various types of display devices such as liquid crystal displays, and organic light emitting diode displays are being utilized.

Among display devices, an organic light emitting display device is a self-luminous and have superior viewing angle and contrast ratio compared to a liquid crystal display LCD. The organic light emitting display device does not require a separate backlight, so it can be lightweight and thin and have the advantage of low power consumption.

Recently, there is an increasing demand for displays that require augmented reality AR, virtual reality VR or an equivalent level of ultra-high resolution, or an equivalent level of ultra-high resolution.

### SUMMARY

Some implementations of the disclosed technology provide a display device with improved reflectivity of reflective electrode.

Some implementations of the disclosed technology provide a display device with improved resistance of connecting electrodes.

Some implementations of the disclosed technology are not limited to those mentioned above, and other technical objects may be inferred from following embodiments.

In one aspect, a display device may include a substrate; a reflective electrode disposed over the substrate and including a first layer, a second layer disposed on the first layer, and a third layer disposed on the second layer; a first electrode disposed over the reflective electrode; a common light-emitting layer disposed over the first electrode; and a second electrode disposed over the common light-emitting layer, wherein the first and second electrodes are structured to supply an electrical signal to the common light-emitting layer to cause emission of light, and wherein the first layer and the third layer of the reflective electrode include a metal, and the second layer of the reflective electrode includes a metal compound.

According to another embodiment, a display device may include a substrate; a reflective electrode supported by the substrate and first layer, a second layer on the first layer, and a third layer on the second layer; a first electrode disposed over the reflective electrode; a common light-emitting layer disposed over the first electrode; and a second electrode disposed over the common light-emitting layer, wherein, the reflective electrode is structured such that a conductivity of the third layer is greater than a conductivity of the first layer and a conductivity of the second layer, and the conductivity of the second layer is greater than the conductivity of the first layer, and a thickness of the second layer is less than a thickness of the first layer and a thickness of the third layer.

According to the embodiments of the present disclosure, the reflectivity of the reflective electrode can be improved by placing the second layer including the metal compound between the first layer including the metal and the third layer to prevent a chemical reaction between the first layer and the third layer.

According to the embodiments of the present disclosure, the resistance of the connecting electrodes can be reduced by placing the fifth layer formed by the metal-organic chemical vapor deposition (MOCVD) method between the fourth and sixth layers formed by the physical vapor deposition (PCV) method.

### BRIEF DESCRIPTION OF THE DRAWINGS

FIG. 1 is a block view of a display device based on some implementations of the disclosed technology.

FIG. 2 is a cross-sectional view of a pixel shown in FIG. 1.

FIG. 3 is a cross-sectional view of an organic light emitting diode shown in FIG. 1.

FIG. 4 is a cross-sectional view of an organic light emitting device according to a modified example of FIG. 3.

FIG. 5 is an enlarged cross-sectional view of Q1 shown in FIG. 2.

FIG. 6 is an enlarged cross-sectional view of Q2 shown in FIG. 5.

FIG. 7 is an example of a flow chart illustrating an effect of a second reflective electrode shown in FIG. 6.

### DETAILED DESCRIPTION

Description will now be given in detail according to exemplary embodiments disclosed herein, with reference to the accompanying drawings.

For the sake of brief description with reference to the drawings, the same or equivalent components may be provided with the same reference numbers, and description thereof will not be repeated. The thicknesses, proportions, and dimensions of the elements are exaggerated for the purpose of effectively illustrating the technical contents. ‘And/or’ includes all combinations of one or more that the related components may define.

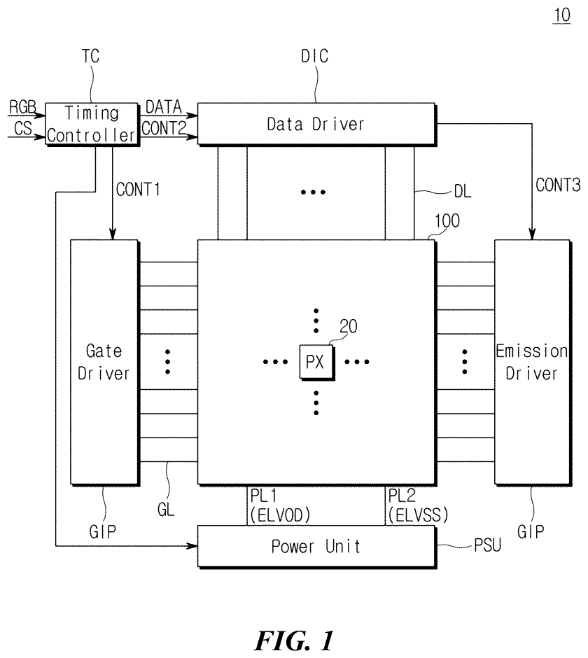

FIG. 1 is a block view of a display device based on some implementations of the disclosed technology.

Referring to FIG. 1, an electronic device 10 may include a display panel 100 that includes panel pixels 20 which emit light for displaying images, a timing controller TC for controlling the timing of the panel pixels 20, a gate driver GIP coupled to the display panel 100, a data driver DIC, an emission driver GIP, a power supply unit PSU coupled to the display panel 100 to supply electric power to the panel pixels 20. In the example, the electronic device 10 may be implemented as the display device. It can be understood that the timing controller TC, the gate driver GIP, the emission driver GIP, the power supply unit PSU, and the display panel 100 are included in the display device.

The timing controller TC may be configured to receive an image signal RGB with color information for each panel pixel 20 (e.g., colors represented by the red (R), green (G) and blue (B) color components) and a control signal CS from an external host system, etc. The image signal RGB may include multiple grayscale data. For example, the control signal CS may include a horizontal synchronization signal, a vertical synchronization signal, and a main clock signal.

The timing controller TC may be configured to process the image signal RGB and the control signal CS to suit the operating conditions of a display panel 100, and to generate and output image data DATA, a gate driving control signal CONT1, a data driving control signal CONT2, an emission driving control signal CONT3, and a power supply control signal CONT4.

The gate driving control signal CONT1 may include scan timing control signal such as a gate start pulse, a gate shift clock, and a gate output enable. The data driving control signal CONT2 may include a data timing control signal such as a source sampling clock, a polarity control signal, and a source output enable.

The gate driver GIP may be configured to sequentially output gate signals for one horizontal period within one frame through a gate line GL in response to the gate driving control signal CONT1 provided from the timing controller TC. Accordingly, a pixel row connected to each gate line GL may be turned on for one horizontal period. During one horizontal period, a data signal may be applied to the pixel row turned on by the gate line GL.

The gate driver GIP may be configured of or include stage circuits each connected to the plurality of gate lines GL, and configured in the form of GIP (Gate In Panel) mounted on the display panel 100. This gate driver GIP may include a shift register, a level shifter, or the like.

The data driver DIC may be configured to convert the digital image data DATA provided from the timing controller TC into an analog data signal based on the data driving control signal CONT2.

The emission driver GIP may be configured to generate light-emitting signals based on the emission driving control signal CONT3 output from the timing controller TC. The emission driver GIP may be configured to provide the generated gate signals to panel pixels 20 through a plurality of emission lines EL.

It is shown in FIG. 1 that the gate driver and the emission driver are separately provided, but other implementations are also possible. For example, the gate driver and the emission driver can be integrated in a single integrated circuit. Hereinafter, the gate driver and the emission driver are integrated and collectively referred to as the gate driver GIP.

Based on the power supply control signal CONT4, the power supply unit PSU may be configured to convert the voltage input from the outside into a high potential voltage ELVDD and a low potential voltage ELVSS, which are standard power sources used inside the electronic device 10. The power supply unit PSU may output the generated driving voltages ELVDD and ELVSS to the components through power lines PL1 and PL2.

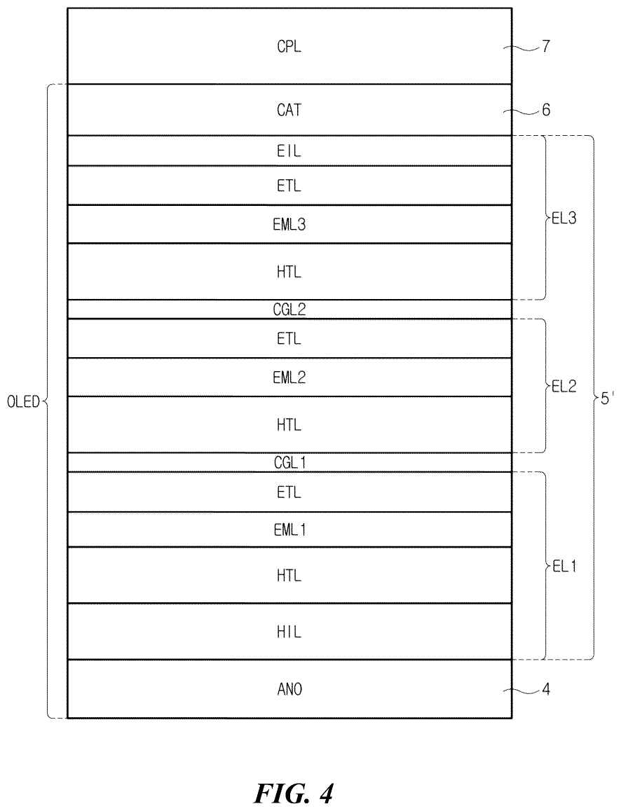

While FIG. 1 shows that the timing controller TC, the data driver DIC, the gate driver GIP, and the power supply unit PSU are provided outside of the display panel 100, other implementations are also possible. For example, in some implementations, the timing controller TC, the data driver DIC, the gate driver GIP, and the power supply unit PSU may be embedded in the display panel 100. In the process of forming the display panel 100, the circuits constituting each of the timing controller TC, the data driver DIC, the gate driver GIP, and the power supply unit PSU may be formed together. The timing controller TC, the data driver DIC, the gate driver GIP, and the power supply unit PSU may each be mounted on a substrate (see 2 of FIG. 4). In some embodiments, the timing controller TC, the data driver DIC, the gate driver GIP, and the power supply unit PSU may be implemented as a separate chip CHIP provided separately from the display panel 100.

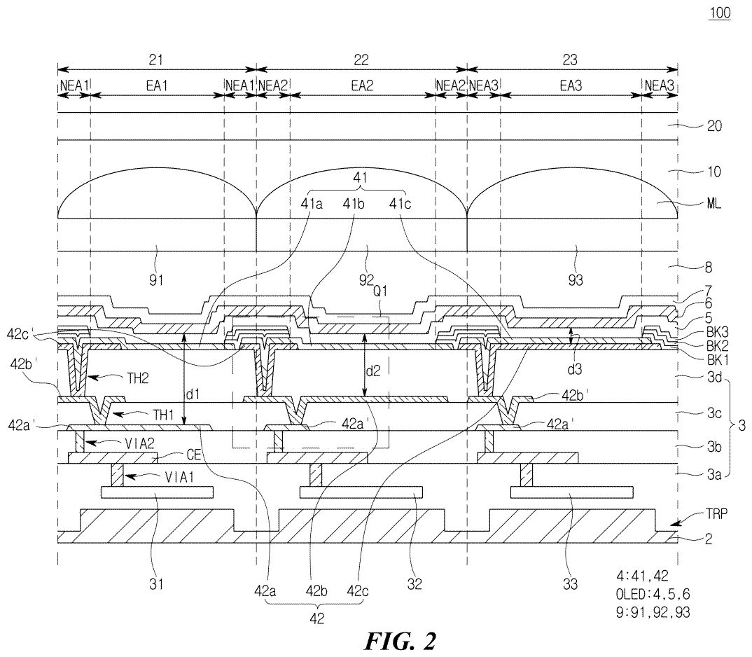

FIG. 2 is a cross-sectional view of one example for implementing each of the panel pixels 20 shown in FIG. 1.

Referring to FIG. 2, the display panel 100 according to one embodiment may include a substrate 2, a first electrode 4, a common light-emitting layer 5, and a second electrode 6. The first electrode 4, the common light-emitting layer 5, and the second electrode 6 may constitute an organic light emitting display OLED where the first electrode 4 and the second electrode 6 supply an electrical signal to the common light-emitting layer 5 to cause emission of light, e.g., white light, for displaying images.

A plurality of sub-pixels 21, 22 and 23 may be disposed on the substrate 2 for emitting light from the common light-emitting layer 5. The plurality of pixels 21, 22 and 23 may form one panel pixel 20 in the display panel 100 in FIG. 1. A plurality of pixels (see 20 of FIG. 1) may be formed on the substrate 2 to form the display panel 100 in FIG. 1.

The plurality of sub-pixels 21, 22 and 23 may include a first sub-pixel 21, a second sub-pixel 22, and a third sub-pixel 23 that are arranged relative to one another in a spatial sequence or pattern. For example, as shown in the example illustrated in FIG. 2, the first pixel, the second sub-pixel 22, and the third sub-pixel 23 are sequentially arranged along a line where the second sub-pixel 22 may be disposed adjacent to one side, for example, the right side of the first sub-pixel 21, and the third sub-pixel 23 may be disposed adjacent to one side, for example, the right side of the second sub-pixel 22.

In some implementations, when arranging two sub-pixels adjacent to each other, there is no other sub-pixel arranged between the two sub-pixels.

The first sub-pixel 21, the second sub-pixel 22, and the third sub-pixel 23 are configured to emit different colored lights from one another. For example, the first sub-pixel 21 may be configured to emit red light R, the second sub-pixel 22 may be configured to emit green light G, and the third sub-pixel 23 may be configured to emit blue light B, but the embodiments are not limited thereto.

FIG. 2 shows that the pixel includes only three sub-pixels, e.g., the sub-pixels 21, 22 and 23, but other implementations are also possible. For example, the pixel may include four sub-pixels. If the pixel includes four sub-pixels, a fourth sub-pixel may be configured to emit white light W.

Each of the first to third sub-pixels 21, 22 and 23 may have the same size. For example, each of the first to third sub-pixels 21, 22 and 23 may have the same width and the same height.

Each of the sub-pixels 21, 22 and 23 may include light-emitting areas EA1, EA2 and EA3 and non-emitting areas NEA1, NEA2 and NEA3. The first sub-pixel 21 may include a first light-emitting area EA1 and a first non-emitting area NEA1 adjacent to the first light-emitting area EA1. The second sub-pixel 22 may include a second light-emitting area EA2 and a second non-emitting area NEA2 adjacent to the second light-emitting area EA2. The third sub-pixel 23 may include a third light-emitting area EA3 and a third non-emitting area NEA3 adjacent to the third light-emitting area EA3. Each light-emitting area EA1, EA2, EA3 may be identical to an area exposed from a bank BK1, BK2, BK3 of the anode electrodes 41a, 41b, 41c described later.

The first electrode 4 is patterned for each individual sub-pixel 21, 22, and 23. The first electrode 4 is supported by the substrate 2. In some implementations, a first portion of the first electrode 4 is formed in the first sub-pixel 21, a second portion of the first electrode 4 is formed in the second sub-pixel 22, and a third portion of the first electrode 4 is formed in the third sub-pixel 23. The first electrode 4 can function as an anode of the display panel 100 to supply an electrical signal (e.g., a current) to the common light-emitting layer 5 to produce light by the sub-pixels 21, 22 and 23. The first electrode 4 can include a reflective electrode 42 and an anode electrode 41. The anode electrode 41 and the reflective electrode 42 can be arranged for each sub-pixel 21, 22 and 23. The anode electrode 41 may include a first anode electrode 41a disposed in the first sub-pixel 21, a second anode electrode 41b disposed in the second sub-pixel 22, and a third anode electrode 41c disposed in the third sub-pixel 23, and the reflective electrode 42 may include a first reflective electrode 42a disposed in the first sub-pixel 21, a second reflective electrode 42b disposed in the second sub-pixel 22, and a third reflective electrode 42c disposed in the third sub-pixel 23. The reflective electrodes 42a, 42b and 42c of each sub-pixel 21, 22 and 23 can be arranged at different heights.

A bank (see BK1, BK2 and BK3 of FIG. 2) may be disposed on each anode electrode 41a, 41b and 41c. The bank BK1, BK2 and BK3 may be configured to cover the edge of the anode electrode 41a, 41b and 41c, thereby enabling the first sub-pixel 21, the second sub-pixel 22 and the third sub-pixel 23 to be distinguished.

The display panel 100 may include reflective electrodes 42a, 42b and 42c disposed for sub-pixels 21, 22 and 23, thereby improving light extraction efficiency by using micro cavity characteristics. In some implementations, the reflective electrodes 42a, 42b, and 42c may have different heights from one another.

The micro cavity characteristic refers to a characteristic in which constructive interference occurs when the distance between the reflective electrodes 42a, 42b and 42c and the second electrode 6 becomes an integer multiple of the half wavelength (λ/2) of light emitted from the sub-pixels 21, 22 and 23, and the light is amplified, and when the reflection and re-reflection process is repeated between the reflective electrodes 42a, 42b and 42c and the second electrode 6, the degree of light amplification continuously increases, thereby improving the external extraction efficiency of light.

The common light-emitting layer 5 may be configured to emit white light. For example, the common light-emitting layer 5 may be provided with a two-stack structure including a blue light-emitting layer, a yellow-green light-emitting layer, and a charge generation layer, or may be provided with a three-stack structure including a blue light-emitting layer, a green light-emitting layer, a red light-emitting layer, and a charge generation layer so as to emit white light. Other implementations are also possible. For example, it may be provided with a plurality of layers exceeding three stacks so long as the multi-stack structure is capable of emitting white light.

The common light-emitting layer 5 may be formed as a common layer over the entire first to third sub-pixels 21, 22 and 23.

The second electrode 6 may be configured to form an electromagnetic field with the anode electrode 41a, 41b and 41c, and function as a cathode. The second electrode 6 may be arranged on the upper surface of the common light-emitting layer 5, which is opposite to the lower surface of the common light-emitting layer 5 with which the anode electrode 41a, 41b and 41c is in contact, and may be provided as a common layer over the entire third to third sub-pixels 21, 22 and 23.

The second electrode 6 may be provided as a second electrode when the display panel 100 operates according to the top emission method in which the light is emitted upward. In some implementation using the lower emission method, in which light is emitted downward, the second electrode 6 may be provided as a first electrode including a reflective material. In case of the top emission method, the second electrode 6 may be formed as a semitransparent electrode to increase light extraction efficiency by using micro cavity characteristic. The display panel 100 is described using the top emission method as an example in which the second electrode 6 is formed as a semitransparent electrode to increase light extraction efficiency by using micro cavity characteristics.

The color filter layer 9 may be provided on each of the first to third sub-pixels 21, 22 and 23, and configured to block a specific color from the light emitted from the common light-emitting layer 5 of each sub-pixel 21, 22 and 23. A first color filter 91 provided on the first sub-pixel 21 may be configured to block other colors other than red light R. In this instance, the first color filter 91 may be provided as a red color filter. The second color filter 92 provided in the second sub-pixel 22 may be configured to block other colors rather than green light G. In this instance, the second color filter 92 may be provided as a green color filter. The third color filter 93 provided in the third sub-pixel 23 may be configured to block other colors rather than blue color B. In this instance, the third color filter 93 may be provided as a blue color filter. However, the embodiments are not limited thereto.

The first to third color filters 91, 92 and 93 provided in the first to third sub-pixels 21, 22 and 23, respectively, may have the same size as the size of each sub-pixel or may have a reduced or enlarged size at a constant ratio to the size of each sub-pixel.

Circuit units 31, 32 and 3 may be arranged in the non-emitting areas NEA1, NEA2 and NEA3 of each sub-pixel 21, 22 and 23, respectively. Each of the circuit units 31, 32 and 33 may include a CMOS circuit or a transistor circuit, but the embodiments are not limited thereto.

The circuit units 31, 32 and 33 may overlap with the reflective electrodes 42a, 42b and 42c arranged in each sub-pixel 21, 22 and 23. The circuit parts 31, 32 and 33 may be electrically connected to the reflective electrodes 42a, 42b and 42c, respectively.

Hereinafter, the laminated structure of the display panel 100 according to one embodiment will be described.

The display panel 100 according to one embodiment may include a substrate 2, an insulating layer 3, a first electrode 4, banks BK1, BK2 and BK3, a common light-emitting layer 5, a second electrode 6, a capping layer 7, an encapsulating layer 8, a color filter layer 9, a micro lens ML, a polarizing layer 10, and a cover layer 20.

The substrate 2 may be or include a plastic film, a glass substrate, or a semiconductor substrate such as silicon. For example, the substrate 2 may be or include a semiconductor substrate.

The substrate 2 may be made of or include a transparent material or opaque material. The first sub-pixel 21, the second sub-pixel 22 and the third sub-pixel 23 may be provided on the substrate 2. The first sub-pixel 21 may be configured to emit red R light, the second sub-pixel 22 may be configured to emit blue B light, and the third sub-pixel 23 may be configured to emit green light G.

The display panel 100 according to one embodiment is formed in the so-called top emission manner in which the light is emitted upward, and therefore, not only a transparent material but also an opaque material can be used as the material of the substrate 2. The color filters 91, 92 and 93 may be provided on the upper side of the first to third sub-pixels 21, 22 and 23 from which the light is emitted, respectively, to transmit light of the same color.

At least one trench portion TRP may be formed in the substrate 2. In the trench portion TRP, the substrate 2 may be recessed in the thickness direction. The trench portion TRP may be arranged corresponding to boundary between adjacent sub-pixels 21, 22 and 23. In some embodiments, multiple trench portions TRP may be provided in one sub-pixel 21, 22 and 23, but the embodiments are not limited thereto. The trench portion TRP may improve the electrical connection between the circuit units 31, 32 and 33 between adjacent sub-pixels 21, 22 and 23 through the substrate 2.

The insulating layer 3 may be formed on the substrate 2. The insulating layer 3 may include an inorganic insulating material. The insulating layer 3 may include a first insulating layer 3a, a second insulating layer 3b on the first insulating layer 3a, a third insulating layer 3c on the second insulating layer 3b, and a fourth insulating layer on the third insulating layer 3c.

In the insulating layer 3, a plurality of circuit units 31, 32 and 33, various signal wires, and circuit elements including capacitors are provided for each sub-pixel 21, 22 and 23. The circuit units 31, 32 and 33 may be arranged in the first insulating layer 3a. The signal wires may include a gate line, a data line, a power line, and a reference line, and the circuit units 31, 32 and 33 may include a CMOS circuit or a thin film transistor. When the circuit portion 31, 32 and 33 includes a thin film transistor, the thin film transistor may include at least one of a switching thin film transistor, a driving thin film transistor, or a sensing thin film transistor. The switching thin film transistor is switched based on the gate signal supplied to the gate line and configured to supply the data voltage supplied from the data line to the driving thin film transistor.

The driving thin film transistor is switched based on the data voltage supplied from the switching thin film transistor and configured to generate data current from the power supplied from the power line and supply it to the first electrode 4.

The sensing thin film transistor is configured to sense the threshold voltage deviation of the driving thin film transistor, which is the cause of image quality deterioration, and supply current of the driving thin film transistor to the reference line in response to a sensing control signal supplied from the gate line or a separate sensing line.

The capacitor is configured to maintain the data voltage supplied to the driving thin film transistor for one frame, and is connected to the gate terminal and source terminal of the driving thin film transistor, respectively.

Each sub-pixel 21, 22 and 23 is defined by the crossing structure of gate lines and data lines. The insulating layer 3 can surround the circuit units 31, 32 and 33.

The first circuit unit 31, the second circuit unit 32, and the third circuit unit 33 are arranged for each individual sub-pixel 21, 22, 23 within the first insulating layer 3a. The first circuit unit 31 is connected to the first electrode 4 arranged on the first sub-pixel 21 and can apply a driving voltage to emit light of a color corresponding to the first sub-pixel 21. The first circuit section 31, the second circuit section 32, and the third circuit section 33 may be located on the same layer, but the embodiments are not limited thereto.

The second circuit unit 32 is connected to the first electrode 4 placed on the second sub-pixel 22 and can apply a driving voltage to emit light of a color corresponding to the second sub-pixel 22.

The third circuit unit (33) is connected to the first electrode (4) placed on the third sub-pixel (23) and can apply a driving voltage to emit light of a color corresponding to the third sub-pixel (23).

Each of the first sub-pixel 21, the second sub-pixel 22, and the third sub-pixel 2) may supply a predetermined current to the light-emitting layer according to the data voltage of the data line when a gate signal is input from the gate line using the respective circuit units 31, 32 and 33. As a result, the light-emitting layer of each of the first sub-pixel 21, the second sub-pixel 22, and the third sub-pixel 23 can emit light with a predetermined brightness according to a predetermined current.

The insulating layer 3 can protect the circuit parts 31, 32 and 33. The insulating layer 3 can be made of or include an inorganic insulating material, but other implementations are also possible. For example, the insulating layer 3 can be made of or include an organic insulating material. For example, the insulating layer 3 may be made of or include an inorganic material such as silicon nitride (SiNx), silicon oxide (SiOx), or aluminum oxide (Al₂O₃), but other implementations are also possible. The first insulating layer 3a, the second insulating layer 3b, the third insulating layer 3c, and the fourth insulating layer 3d may be made of or include inorganic materials such as silicon nitride (SiNx), silicon oxide (SiOx), or aluminum oxide (Al₂O₃), but other implementations are also possible.

A connecting electrode CE and a plurality of electrode patterns may be arranged on the insulating layer 3. The plurality of electrode patterns may include a connecting electrode CE on the first insulating layer 3a, a first electrode pattern 42a, 42a′ on the second insulating layer 3b, a second electrode pattern 42b, 42b′ on the third insulating layer 3c, and a third electrode pattern 42c, 42c′ on the fourth insulating layer 3d. The first electrode pattern 42a, 42a′ may include a first reflective electrode 42a and a first connecting electrode 42a′, the second electrode pattern 42b, 42b′ may include a second reflective electrode 42b and a second connecting electrode 42b′, and the third electrode pattern 42c, 42c′ may include a third reflective electrode 42c and a third connecting electrode 42c′. In the example as shown in FIG. 2, the first connecting electrode 42a′ and the first reflective electrode 42a are disposed at a first level, the second connecting electrode 42b′ and the second reflective electrode 42b are disposed at a second level, and the third connecting electrode 42c′ and the third reflective electrode 42c are disposed at a third level. Referring to FIG. 2, the first level is on the second insulating layer, the second level is on the third insulating layer 3c, and the third level is on the fourth insulating layer 3d.

The connecting electrodes CE may be placed in each of the sub-pixels 21, 22 and 23. The connecting electrodes CE are placed in each of the first sub-pixel 21, the second sub-pixel 22, and the third sub-pixel 23, and may be placed on the first insulating layer 3a. The connecting electrodes CE of each sub-pixel 21, 22 and 23 can be electrically connected to each circuit unit 31, 32 and 33 through a first via VIA. The first via VIA1 can include copper (Cu) or tungsten (W), but the embodiments of the present specification are not limited thereto. The first via VIA1 can be filled in a hole that recesses the first insulating layer 3a in the thickness direction. The hole of the first insulating layer 3a in which the first via VIA1 is formed can include one inclined surface. One inclined surface can mean that the inclined surface is formed at one inclined angle.

The first reflective electrode 42a and the first connecting electrode 42a′ are arranged on the same layer and may include the same material. The second reflective electrode 42b and the second connecting electrode 42b′ may be arranged on the same layer and may include the same material. The third reflective electrode 42c and the third connecting electrode 42c′ may be arranged on the same layer and may include the same material.

Each electrode pattern may include a reflective material for reflecting light. For example, the reflective material may be a metal, but other implementations are also possible. For example, the reflective metal may be or include any other material capable of reflecting light without being limited to the metal. The materials that form each electrode pattern will be described later.

The reflective electrodes (42: 42a, 42b and 42c) are positioned at a relatively lower position than the common light-emitting layer 5 that emits light, so that the light emitted from the common light-emitting layer 5 can be reflected upward. Here, the upper side means the direction in which the user can perceive the light, and may mean, for example, the side where the encapsulating layer 8 or the color filter layer 9 is positioned. Accordingly, the light efficiency of the first sub-pixel 21, the second sub-pixel 22, and the third sub-pixel 23 can be further improved compared to the case where there are no reflective electrodes (42: 42a, 42b and 42c), and the user can perceive a high-brightness, i.e., clear image through the improved light efficiency.

The first reflective electrode 42a is disposed on the second insulating layer 3b in the first sub-pixel 21, and the first connecting electrodes 42a′ can be disposed on the second insulating layer 3b in each of the sub-pixels 21, 22 and 23, and can be connected to the first reflective electrode 42a in the first sub-pixel 21. The first connecting electrodes 42a′ arranged in each sub-pixel 21, 22 and 23 can be electrically connected to the connecting electrode CE through the second via VIA2. The second via VIA2 can include copper (Cu) or tungsten (W), but the embodiments of the present specification are not limited thereto. The second via VIA2 can be filled in a hole that recesses the second insulating layer 3b in the thickness direction. The hole in the second insulating layer 3b in which the second via VIA2 is formed can include one inclined surface.

The first reflective electrode 42a is placed in the first light-emitting area EA1 and may also be placed in the first non-emitting area NEA1. In the present disclosure, the first connecting electrode 42a′ is exemplified as being disposed in the first non-emitting area NEA1 and a portion thereof extending to the first emitting area EA1, but the embodiments of this specification are not limited thereto, and the first connecting electrode 42a′ may be disposed only in the first non-emitting area NEA1.

A third insulating layer 3c may be placed on the first reflective electrode 42a and the first connecting electrode 42a′.

The second reflective electrode 42b may be placed on the third insulating layer 3c in the second sub-pixel 22, and the second connecting electrodes 42b′ may be placed on the third insulating layer 3c in the sub-pixels 21, 22 and 23, respectively. The second connecting electrodes 42b′ arranged in each sub-pixel 21, 22 and 23 can be electrically connected to the first connecting electrode 42a′ at the bottom in the first through-hole TH1. The third insulating layer 3c can be recessed in the thickness direction in the first through-hole TH1. In the first sub-pixel 21, the second connecting electrode 42b′ may be electrically connected to the first connecting electrode 42a′ in the first through-hole TH1, in the second sub-pixel 22, the second connecting electrode 42b′ may be electrically connected to the first connecting electrode 42a′ in the first through-hole TH1, and in the third sub-pixel 23, the second connecting electrode 42b′ may be electrically connected to the first connecting electrode 42a′ in the first through-hole TH1. In FIG. 2, the first through hole TH1 is exemplified as being positioned in the light-emitting areas EA1, EA2 and EA3, but the first through-hole TH1 may also be positioned in the non-emitting areas NEA1, NEA2 and NEA3.

A fourth insulating layer 3d may be placed on the second reflective electrode 42b and the second connecting electrode 42b′.

The third reflective electrode 42c is disposed on the fourth insulating layer 3d in the third sub-pixel 23, and the third connecting electrodes 42c′ may be disposed on the fourth insulating layer 3d in the sub-pixels 21, 22 and 23, respectively. The third connecting electrodes 42c′ disposed in each sub-pixel 21, 22 and 23 can be electrically connected to the second connecting electrode 42b′ at the bottom in the second through hole TH2. In the second through hole TH2, the fourth insulating layer 3d may be recessed in the thickness direction. In the first sub-pixel 21, the third connection electrode 42c′ may be electrically connected to the second connecting electrode 42b′ in the second through hole TH2, in the second sub-pixel 22, the third connecting electrode 42c′ may be electrically connected to the second connecting electrode 42b′ in the second through hole TH2, and in the third sub-pixel 23, the third connecting electrode 42c′ may be electrically connected to the second connecting electrode 42b′ in the second through hole TH2. In FIG. 2, the second through hole TH2 is exemplified as being positioned in the light-emitting areas EA1, EA2 and EA3, but the second through hole TH2 may also be positioned in the non-emitting areas NEA1, NEA2 and NEA3.

Although not shown, a trench (not shown) may be formed in at least one of the insulating layers 3a, 3b, 3c and 3d. For example, the trench may be formed in the non-emitting are NEA1, NEA2 and NEA3, but the embodiments of the present disclosure are not limited thereto. The trench may be configured to prevent lateral leakage current LLC due to the common light-emitting layer 5 between adjacent sub-pixels 21, 22 and 23.

As shown in FIG. 2, In the light-emitting areas EA1, EA2 and EA3, the distances between the reflective electrodes 42a, 42b and 42c and the second electrode 6 may be different from each other. For example, the distance between the first reflective electrode 42a and the second electrode 6 may be the largest, then the distance between the second reflective electrode 42b and the second electrode 6 may be the largest, and finally, the distance between the third reflective electrode 42c and the second electrode 6 may be the smallest.

In this way, the reflective electrodes 42a, 42b and 42c are formed to have various distances (or resonance distances) from the second electrode 6 because the light extraction efficiency of different colors can be improved through reflection and re-reflection between the reflective electrodes 42a, 42b and 42c and the second electrode 6 based on the distance. Accordingly, the light extraction efficiency of red light can be improved in the first sub-pixel 21, the light extraction efficiency of green light can be improved in the second sub-pixel 22, and the light extraction efficiency of blue light can be improved in the third sub-pixel 23.

The anode electrode 41 may include a first anode electrode 41a of the first sub-pixel 21, a second anode electrode 41b of the second sub-pixel 22, and a third anode electrode 41c of the third sub-pixel 23. The anode electrodes 41a, 41b and 41c may be arranged in the same layer and include the same material.

In each sub-pixel 21, 22 and 23, the anode electrodes 41a, 41b and 41c can be directly placed on the third connection electrode 42c′ or the third reflective electrode 42c. In each sub-pixel 21, 22 and 23, the anode electrodes 41a, 41b and 41c can be electrically connected to the third connecting electrode 42c′ or the third reflective electrode 42c. The anode electrodes 41a, 41b and 41c are respectively arranged in the light-emitting areas EA1, EA2 and EA3 and can be extended and arranged even in some non-emitting areas NEA1, NEA2 and NEA3.

The anode electrode 41a, 41b and 41c may include a material having high light transmittance. The anode electrode 41a, 41b and 41c may be provided transparently so that light reflected from the reflective electrode 42a, 42b and 42c may proceed upward. The anode electrode 41a, 41b and 41c may be formed of a transparent material, but the embodiments are not limited thereto, and may be formed of a metal material in the form of a thin film as long as it can transmit light. For example, the anode electrode 41a, 41b and 41c may include TiN (titanium nitride), but the embodiments are not limited thereto. For example, when the anode electrode 41a, 41b and 41c includes TiN, the thickness may be about 5 nm or less. For example, the thickness of the anode electrode 41a, 41b and 41c may be about 3 nm or less, but the embodiments are not limited thereto. For example, the anode electrode 41a, 41b and 41c may also include a transparent conductive oxide such as ITO or IZO.

A bank may be arranged on the anode electrode 41a, 41b and 41c. The bank may be composed of a plurality of layers, but the embodiments of the present disclosure are not limited thereto. For example, the bank may include three stacked banks BK1, BK2 and BK3.

The banks BK1, BK2 and BK3 may be made of or include an inorganic material such as silicon nitride (SiNx), silicon oxide (SiOx), or aluminum oxide (Al2O3), but the embodiments are not limited thereto. For example, the first bank BK1 may include aluminum oxide (Al2O3), the second bank BK2 may include silicon oxide (SiOx), and the third bank BK3 may include silicon nitride (SiNx), but the embodiments are not limited thereto.

The banks (BK1, BK2, BK3) can be arranged on the non-emissive areas (NEA1, NEA2, NEA3). In the emissive areas (EA1, EA2, EA3), the banks (BK1, BK2, BK3) can expose the upper surface of the anode electrodes (41a, 41b, 41c) to define the emissive areas (EA1, EA2, EA3).

The banks BK1, BK2 and BK3 can be arranged on the non-emitting areas NEA1, NEA2 and NEA3. In the light-emitting areas EA1, EA2 and EA3, the banks BK1, BK2 and BK3 can expose the upper surface of the anode electrodes 41a, 41b and 41c to define the light emissive areas EA1, EA2 and EA3.

An organic light emitting device (OLED) according to one embodiment may include an anode electrode 41 (ANO, or a first electrode 4), a second electrode 6 (CAT), and a common layer 5 between the first electrode 4 and the second electrode 6.

The common light-emitting layer 5 may be provided to emit white W light. To this end, the common light-emitting layer 5 may be formed by including a plurality of stacks that emit light of different colors. Specifically, the common light-emitting layer 5 may be formed by including a first stack, a second stack, and a charge generation layer CGL provided between the first stack and the second stack.

The second electrode 6 is formed on the common light-emitting layer 5. The second electrode 6 can function as a cathode of the display panel 100. The second electrode 6 is formed on each sub-pixel 21, 22 and 23 and between them, similar to the common light-emitting layer 5.

In a display panel 100 according to one embodiment, the second electrode 6 may be formed as a semitransparent electrode to implement white light with light efficiency in a top emission manner. Accordingly, a micro cavity effect can be obtained for each of the first to third sub-pixels 21, 22 and 23. Since the micro cavity effect can be obtained by repeating the reflection and re-reflection of light between the second electrode 6 and the reflective electrode 42, the light extraction efficiency can be improved.

In some implementations, since the second electrode 6 is formed on the upper surface of the common light-emitting layer 5, the second electrode 6 can be formed along the profile of the common light-emitting layer 5. Since the common light-emitting layer 5 is formed along the profile of the first electrode 4 in the light-emitting area, the second electrode 6 can be formed along the profile of the first electrode 4. In addition, the capping layer 7 on the second electrode 6 can also be formed along the profile of the second electrode 6.

The capping layer 7 may be made of or include an inorganic insulating material, but the embodiments are not limited thereto. The capping layer 7 may be placed on the second electrode 6 to protect the organic light-emitting device OLED.

The encapsulating layer 8 is formed on the second electrode 6 and configured to prevent external moisture from penetrating into the common light-emitting layer 5. Such the encapsulating layer 8 may be formed of or include an inorganic insulating material or may have a structure in which an inorganic insulating material and an organic insulating material are alternately laminated. The materials and structures of the encapsulation layer 8 as described above are examples only and other implementations are also possible.

The color filter layer 9 is formed on the encapsulating layer 8. The color filter layer 9 may include a first color filter 91 of red R provided in the first sub-pixel 21, a second color filter 92 of green G provided in the second sub-pixel 22, and a third color filter 93 of blue B provided in the third sub-pixel 23, but the embodiments are not necessarily limited to. Although not shown, a black matrix may be provided between the first to third color filters 91, 92 and 93 to prevent color mixing between sub-pixels.

A micro lens ML may be placed on the color filter layer 9 to focus light incident from the outside. A plurality of micro lenses ML may be provided and placed for each sub-pixel 21, 22 and 23.

The planarizing layer 10 may be placed on the micro lens ML, and a cover layer 20 may be placed on the planarizing layer 10. The cover layer 20 may include glass or plastic, but the embodiments of the present disclosure are not limited thereto.

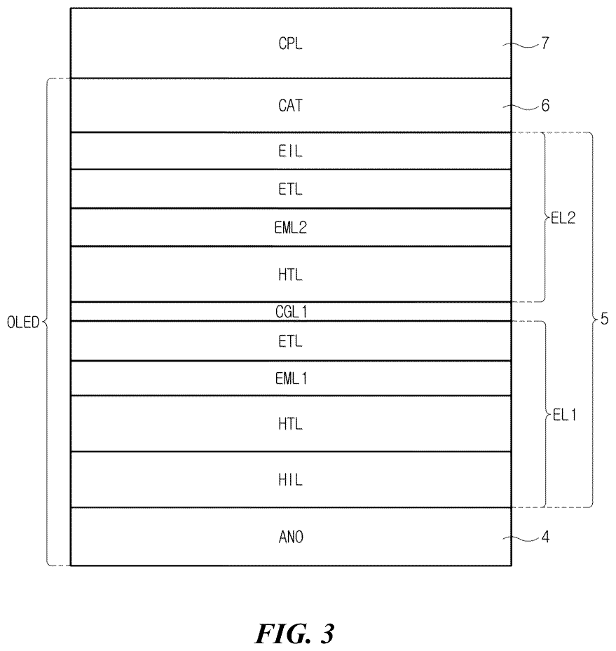

FIG. 3 is a cross-sectional view of an organic light emitting diode according to FIG. 1. FIG. 4 is a cross-sectional view of an organic light emitting device according to a modified example of FIG. 3.

Referring to FIGS. 2 and 3, the common light-emitting layer 5 may be formed by including a first stack EL1, a second stack EL2, and a first charge generation layer CGL1 provided on the first electrode 4.

The first stack EL1 is provided on the first electrode 4 and may have a structure in which a hole injection layer HIL, a hole transport layer HTL, a blue B emitting layer EML1, and an electron transport layer ETL are sequentially stacked.

The first stack EL1 can also be placed between the first sub-pixel 21 and the second sub-pixel 22, and between the second sub-pixel 22 and the third sub-pixel 23.

The first charge generation layer CGL1 serves to supply charges to the first stack EL1 and the second stack EL2. The first charge generation layer CGL1 may include an N-type charge generation layer for supplying electrons to the first stack EL1 and a P-type charge generation layer for supplying holes to the second stack EL2). The above N-type charge generation layer can be formed by including a metal material as a dopant.

The second stack EL2 is provided on the first stack EL1 and may have a structure in which a hole transport layer HTL, a yellow green (YG) emitting layer EML2, an electron transport layer ETL, and an electron injection layer EIL are sequentially laminated.

The second stack EL2 can also be placed between the first sub-pixel 21 and the second sub-pixel 22, and between the second sub-pixel 22 and the third sub-pixel 23

As a result, the common light-emitting layer 5 can be provided as a common layer throughout the first to third sub-pixels 21, 22 and 23, as shown in FIGS. 2 and 3.

As shown in FIG. 2 and FIG. 4, a common light-emitting layer 5′ of the organic light-emitting device OLED according to one embodiment may include a first stack EL1, a second stack EL2, a third stack EL3 provided on a first electrode 4, a first charge generation layer CGL1 between the first stack EL1 and the second stack EL2, and a second charge generation layer CGL2 between the second stack EL2 and the third stack EL3.

The first stack EL1 is provided on the first electrode 4 and may have a structure in which a hole injection layer HIL, a hole transport layer HTL, a blue B emitting layer EML1, and an electron transport layer ETL are sequentially laminated.

The first stack EL1 can also be placed between the first sub-pixel 21 and the second sub-pixel 22, between the second sub-pixel 22 and the third sub-pixel 23, that is, on the banks (BK1, BK2 and BK3.

The first charge generation layer CGL1 serves to supply charges to the first stack EL1 and the second stack EL2. The first charge generation layer CGL1 may include an N-type charge generation layer for supplying electrons to the first stack EL1 and a P-type charge generation layer for supplying holes to the second stack EL2. The N-type charge generation layer may be formed by including a metal material as a dopant.

The second stack EL2 is provided on the first stack EL1 and may have a structure in which a hole transport layer HTL, a green G emitting layer EML2, and an electron transport layer ETL are sequentially stacked.

The second stack EL2 can also be placed between the first sub-pixel 21 and the second sub-pixel 22, between the second sub-pixel 22 and the third sub-pixel 23, that is, on the banks BK1, BK2 and BK3.

The second charge generation layer CGL2 serves to supply charges to the second stack EL2 and the third stack EL3. The second charge generation layer CGL2 may include an N-type charge generation layer for supplying electrons to the second stack EL2 and a P-type charge generation layer for supplying holes to the third stack EL3. The N-type charge generation layer may be formed by including a metal material as a dopant.

The third stack EL3 is provided on the second stack EL2 and may have a structure in which a hole transport layer HTL, a red R emitting layer EML3, an electron transport layer ETL, and an electron injection layer EIL are sequentially stacked.

As shown in FIGS. 2, 3, and 4, the charge generation layers CGL1 and CGL2 may also be arranged between the first sub-pixel 21 and the second sub-pixel 22, and between the second sub-pixel 22 and the third sub-pixel 23. Meanwhile, in the display panel 100 according to one embodiment, since the common light-emitting layer 5 is also arranged between each of the sub-pixels 21, 22 and 23), when one of the sub-pixels emits light, a lateral leakage current may occur to the adjacent sub-pixel 21, 22 and 23 through the charge generation layer CGL1 and CGL2, but the above-described trench may be formed between the sub-pixels 21, 22 and 23. The length of the formation of the common light-emitting layer 5 at the boundary of the sub-pixels 21, 22 and 23 through the trench can be increased, thereby lengthening the current path. As a result, the occurrence of lateral leakage current can be prevented. Furthermore, the common light-emitting layer 5 can be separated from the trench, thereby preventing lateral leakage current in advance.

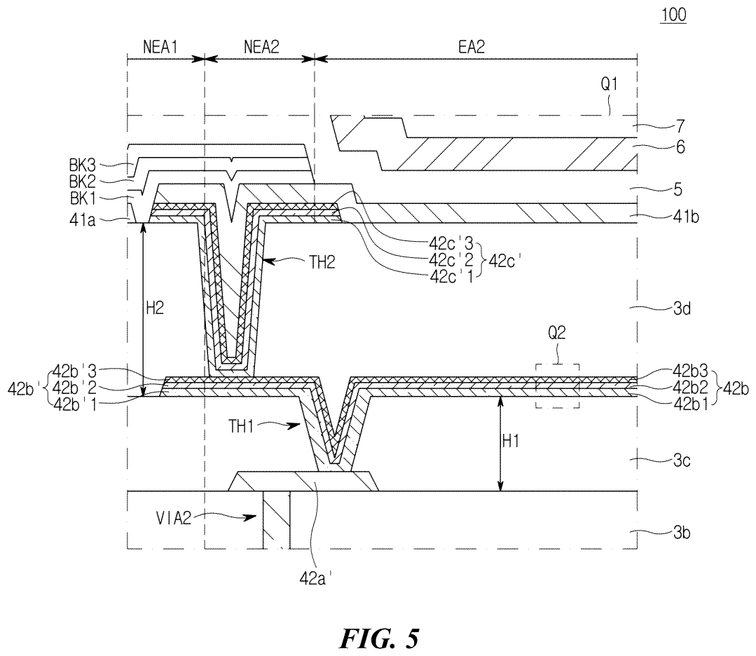

FIG. 5 is an enlarged cross-sectional view of Q1 shown in FIG. 2. In FIG. 5, only the second electrode pattern 42b and 42b′ and the third connecting electrode 42c′ located in the second light-emitting area EA2 and the second non-emitting area NEA2 are illustrated, but the type, number, thickness of the conductive layers constituting the second electrode pattern 42b and 42b′, or the characteristics of the two conductive layers may be the same as the type, number, thickness of the conductive layers, or the characteristics of the two conductive layers constituting the first electrode pattern 42a and 42a′ and the third electrode pattern 42c and 42c′.

For example, the second reflective electrode 42b may include a first layer 42b1, a second layer 42b2, and a third layer 42b3, and the second layer 42b2 may be disposed between the first layer 42b1 and the third layer 42b3.

The second connecting electrode 42b′ may include a fourth layer 42b′1, a fifth layer 42b′2, and a sixth layer 42b′3, and the fifth layer 42b′2 can be placed between the fourth layer 42b′1 and the sixth layer 42b′3.

The third connecting electrode 42c′ includes a seventh layer 42c′1, an eighth layer 42c′2, and a ninth layer 42c′3, and the eighth layer 42c′2 can be placed between the seventh layer 42c′1 and the ninth layer 42c′3.

As described above, the first layer 42b1 may be identical to the fourth layer 42b′1 and the seventh layer 42c′1, the second layer 42b2 may be identical to the fifth layer 42b′2 and the eighth layer 42c′2, and the third layer 42b3 may be identical to the sixth layer 42b′3 and the ninth layer 42c′3.

Hereinafter, the explanation will focus on the second reflective electrode 42b.

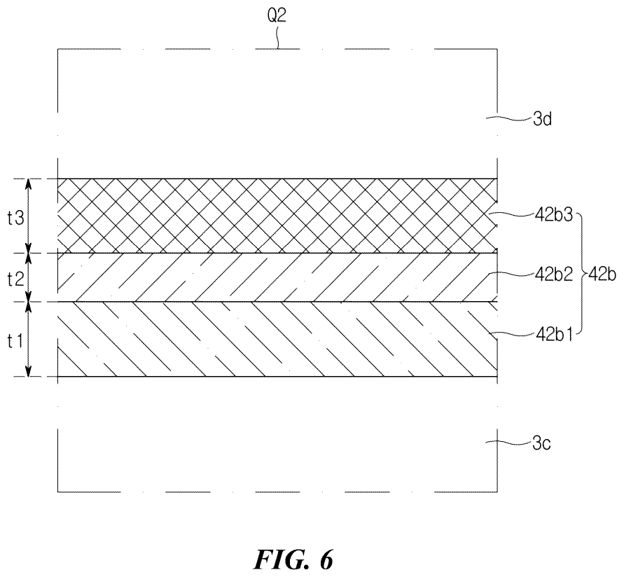

FIG. 6 is an enlarged cross-sectional view of Q2 shown in FIG. 5.

Referring to FIG. 6, the second reflective electrode 42b may include a first layer 42b1, a second layer 42b2 on the first layer 42b1, and a third layer 42b3 on the second layer 42b2.

The first layer 42b1 and the third layer 42b3 may include a metal, and the second layer 42b2 may include a metal compound. For example, the conductivity (or electrical conductivity) of the third layer 42b3 may be greater than the conductivity of the second layer 42b2 and the first layer 42b1.

In addition, the thickness t2 of the second layer 42b2 may have a value between the thickness t1 of the first layer 42b1 and the thickness t3 of the third layer 42b3. For example, the thickness t2 of the second layer 42b2 may be about 0.08 to about 0.5 times the thickness t3 of the third layer 42b3, and may be about 0.2 to about 1.0 times the thickness t1 of the first layer 42b1.

For example, the first layer 42b1 may include titanium (Ti), the third layer 42b3 may include aluminum (Al), and the second layer 42b2 may include titanium nitride (TiN), but the embodiments are not limited thereto.

For example, the bonding energy between titanium (Ti) and nitride (N) may be greater than the bonding energy between titanium (Ti) and aluminum (Al). According to one embodiment, compared to a conventional reflective electrode having a laminated structure of titanium (Ti) and aluminum (Al), the thermal stability of the reflective electrode can be improved by additionally laminating titanium nitride (TiN), which has higher thermal stability, between titanium (Ti) and aluminum (Al).

Below, the reflectivity according to the thickness of the first layer 42b1 to the third layer 42b3 will be described.

TABLE 1

| | | | | Reflectance | | |
|---|---|---|---|---|---|---|
| | Thickness (nm) | | | Before | After | |
| Sample | Ti | TiN | Al | Annealing | Annealing | Difference(%) |
| S1 | 20 | 2 | 50 | 89.5 | 77.66 | −13.11 |
| S2 | 20 | 2.5 | 50 | 89.95 | 80.84 | −10.13 |
| S3 | 20 | 3 | 50 | 89.9 | 82.08 | −8.7 |
| S4 | 20 | 3.5 | 50 | 90.02 | 83.95 | −6.74 |
| S5 | 20 | 4 | 50 | 90.07 | 88.69 | −1.52 |
| S6 | 20 | 10 | 50 | 90.04 | 89.15 | −0.99 |
| S7 | 20 | 20 | 50 | 90.06 | 89.07 | −1.1 |

According to the samples in Table 1, the first layer 42b1 may include titanium, the second layer 42b2 may include titanium nitride, and the third layer 42b3 may include aluminum.

Additionally, the thicknesses of titanium and aluminum were fixed at 20 nm and 50 nm, respectively.

‘Annealing’ described in Table 1 means a high temperature process, and may be, for example, a process for activating a semiconductor layer of a circuit portion 31, 32 and 33 illustrated in FIG. 2. For example, the high temperature condition of annealing may be about 200 degrees or higher, but is not limited thereto.

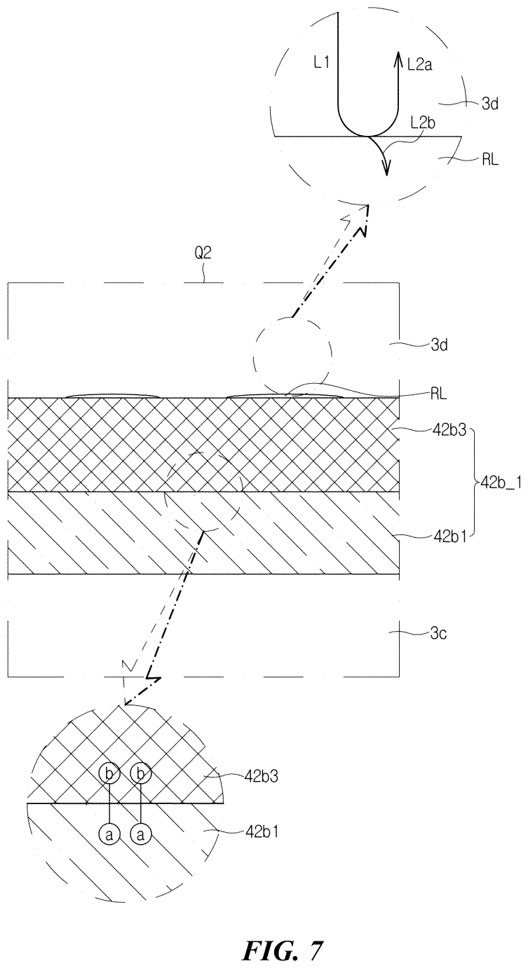

FIG. 7 is a flow chart to describe an effect of a second reflective electrode shown in FIG. 6.

Referring to Table 1 and FIG. 7 together, FIG. 7 is about a conventional second reflective electrode 42b_1 structure, and shows a double-layer conductive structure in which the second layer is omitted and the third layer 42b3 is directly placed on the first layer 42b1. In addition, FIG. 7 shows the structure of the second reflective electrode 42b_1 after annealing.

Referring to FIG. 7, after annealing under high temperature conditions, a chemical bond can be formed between the material b (ion) constituting the third layer 42b3 and the material c (ion) constituting the first layer 42b1 (the chemically bonded material is referred to as a residual compound hereinafter). The residual compound can move to the surface (or upper surface) of the third layer 42b3. As described above, since the annealing process is a high-temperature process, the residual compound can diffuse to the surface of the third layer 42b3 under high-temperature conditions. The above residual compound can form a residual layer RL on the upper surface of the third layer 42b3. The residual layer RL is in direct contact with the surface of the third layer 42b3, and the surface of the third layer 42b3 in the area where the residual layer RL is not disposed can be exposed.

As shown in FIG. 7, light L1 passing through the fourth insulating layer 3d can enter the residual layer RL. The reflectivity of the residual layer RL can be significantly lower than the reflectivity of the third layer 42b3. Accordingly, light L1 can be divided into light L2a reflected from the residual layer RL and light L2b transmitting through the residual layer RL, so that the reflectivity of the second reflective electrode 42b_1 can be reduced.

However, according to Table 1 and FIG. 6, the second reflective electrode 42b according to one embodiment has a second layer 42b2 having a high film density disposed between the first layer 42b1 and the third layer 42b3, thereby preventing the formation of the residual compound at the interface between the first layer 42b1 and the third layer 42b3.

In addition, as confirmed in Table 1, the second layer 42b2 according to one embodiment can minimize the decrease in reflectivity of the second reflective electrode 42b after annealing by having a thickness of titanium nitride that is about 0.2 times or more the thickness of titanium and about 0.08 times or more the thickness of aluminum (corresponding to samples (S5 to S7)).

Below, the resistance according to the thickness of the 4th layer 42b′1 to the 6th layer 42b′3 of FIG. 5 will be described.

TABLE 2

| | | | | Resistance | | |
|---|---|---|---|---|---|---|
| | Thickness(nm) | | | Before | After | |
| Sample | Ti | TiN | Al | Annealing | Annealing | Difference(%) |
| S1 | 20 | 2 | 50 | 0.71 | 3.09 | 337.14 |
| S2 | 20 | 2.5 | 50 | 0.71 | 2.45 | 245.24 |
| S3 | 20 | 3 | 50 | 0.71 | 2.22 | 212.01 |
| S4 | 20 | 3.5 | 50 | 0.74 | 1.90 | 155.49 |
| S5 | 20 | 4 | 50 | 0.73 | 0.91 | 24.65 |
| S6 | 20 | 10 | 50 | 0.74 | 0.87 | 17.84 |
| S7 | 20 | 20 | 50 | 0.74 | 0.89 | 19.53 |

According to the samples in Table 2, the fourth layer 42b′1 may include titanium, the fifth layer 42b′2 may include titanium nitride, and the sixth layer 42b′3 may include aluminum.

Additionally, the thicknesses of titanium and aluminum were fixed at 20 nm and 50 nm, respectively.

The high temperature annealing conditions in Table 2 are the same as those described in Table 1.

As described above in FIG. 7, after annealing under high temperature conditions, a chemical bond is formed between the material (b) (ion) constituting the third layer (42b3) and the material (c) (ion) constituting the first layer (42b1), and the residual compound remains inside the second connecting electrode, thereby increasing the resistance of the second connecting electrode.

However, according to Table 2 and FIG. 5, the second connecting electrode 42b′ according to one embodiment has a fifth layer 42b′2 having a high film density disposed between the fourth layer 42b′1 and the sixth layer 42b′3, thereby preventing the formation of the residual compound at the interface between the fourth layer 42b′1 and the sixth layer 42b′3.

In addition, as confirmed in Table 2, the fifth layer 42b′2 according to one embodiment has a thickness of titanium nitride that is about 0.2 times or more the thickness of titanium and about 0.08 times or more the thickness of aluminum (corresponding to samples (S5 to S7)), thereby minimizing an increase in the resistance of the second reflective electrode 42b after annealing.

In addition, the titanium nitride constituting the fifth layer 42b′2 according to one embodiment is formed through a metal organic chemical vapor deposition (MOCVD) method, while the fourth layer 42b′1 and the sixth layer 42b′3 are formed through a physical vapor deposition (PCV) method. The fourth layer 42b′1 and the sixth layer 42b′3 formed through the physical vapor deposition (PCV) method have difficulties in forming with a uniform thickness due to the limitations of the deposition method, but the fifth layer 42b′2 formed through the metal-organic chemical vapor deposition (MOCVD) method can be formed with a relatively uniform thickness. Therefore, as shown in Table 2, as the thickness of titanium nitride increases, there is an effect of improving the resistance of the second connection electrode overall.

The display device according to the various embodiments of the present specification can be described as follows.

The display device according to the embodiments of the present disclosure may include a substrate; a reflective electrode on the substrate; a first electrode on the reflective electrode; a common light-emitting layer on the first electrode; and a second electrode on the common light-emitting layer. The reflective electrode may include a first layer, a second layer on the first layer, and a third layer on the second layer, and the first layer and the third layer may include metal, and the second layer may include a metal compound.

The first layer may include titanium (Ti), the second layer includes titanium nitride (TiN), and the third layer includes aluminum (Al).

The bonding energy between the materials constituting the second layer may be higher than the bonding energy between the first layer and the third layer.

The thickness of the second layer may be less than the thickness of the first layer and the thickness of the third layer.

The thickness of the second layer may be 0.08 to 0.5 times the thickness of the third layer and 0.2 to 1 times the thickness of the first layer.

The substrate may include a first sub-pixel, a second sub-pixel, and a third sub-pixel, the reflective electrode may include a first reflective electrode on the first sub-pixel, a second reflective electrode on the second sub-pixel, and a third reflective electrode on the third sub-pixel. A distance between the first reflective electrode and the first electrode in the first sub-pixel may be greater than a distance between the second reflective electrode and the first electrode in the second sub-pixel and a distance between the third reflective electrode and the first electrode in the third sub-pixel. A distance between the second reflective electrode and the first electrode in the second sub-pixel may be greater than a distance between the third reflective electrode and the first electrode in the third sub-pixel.

The third reflective electrode may be in direct contact with the first electrode.

The display device according to the embodiments of the present disclosure may further include a circuit unit between the substrate and the reflective electrode; a first connecting electrode on the same layer as the first reflective electrode; a second connecting electrode on the same layer as the second reflective electrode; and a third connecting electrode on the same layer as the third reflective electrode. In each sub-pixel, the first connecting electrode may be electrically connected to the circuit portion, the second connecting electrode may be electrically connected to the first connecting electrode, and the third connecting electrode may be electrically connected to the second connecting electrode.

Each of the connecting electrodes may include a fourth layer, a fifth layer on the fourth layer, and a sixth layer on the fifth layer, the fourth layer may include the same material as the first layer, the fifth layer may include the same material as the second layer, and the sixth layer may include the same material as the third layer.

The fourth layer may include titanium (Ti), the fifth layer includes titanium nitride (TiN), and the sixth layer may include aluminum (Al).

The bonding energy between the materials constituting the fifth layer may be higher than bonding energy between the fourth layer and the sixth layer.

The thickness of the fifth layer may be less than the thickness of the fourth layer and the thickness of the sixth layer.

The thickness of the fifth layer may be 0.08 to 0.5 times the thickness of the sixth layer and 0.2 to 1 times the thickness of the fourth layer.

According to the embodiments of the present disclosure, a display device may include a substrate; a reflective electrode on the substrate; a first electrode on the reflective electrode; a common light-emitting layer on the first electrode; and a second electrode on the common light-emitting layer. The reflective electrode may include a first layer, a second layer on the first layer, and a third layer on the second layer, and the conductivity of the third layer may be greater than the conductivity of the first layer and the conductivity of the second layer. The conductivity of the second layer may be greater than the conductivity of the first layer, and the thickness of the second layer may be less than the thickness of the first layer and the thickness of the third layer.

The first layer and the third layer may include a metal, and the second layer may include a metal compound.

The first layer may include titanium (Ti), the second layer may include titanium nitride (TiN), and the third layer may include aluminum (Al).

The bonding energy between the materials constituting the second layer may be higher than the bonding energy between the first layer and the third layer.

The thickness of the second layer may be 0.08 to 0.5 times the thickness of the third layer and 0.2 to 1 times the thickness of the first layer.

The display device may further include a circuit unit between the substrate and the reflective electrode; a first connecting electrode on the same layer as the first reflective electrode; a second connection electrode on the same layer as the second reflective electrode; and a third connecting electrode on the same layer as the third reflective electrode. The substrate may include a first sub-pixel, a second sub-pixel, and a third sub-pixel. The reflective electrode may include a first reflective electrode on the first sub-pixel, a second reflective electrode on the second sub-pixel, and a third reflective electrode on the third sub-pixel. In each of the sub-pixels, the first connecting electrode may be electrically connected to the circuit portion, the second connecting electrode may be electrically connected to the first connecting electrode, and the third connecting electrode may be electrically connected to the second connecting electrode. Each of the connecting electrodes may include a fourth layer, a fifth layer on the fourth layer, and a sixth layer on the fifth layer. The fourth layer may include the same material as the first layer, the fifth layer includes the same material as the second layer, and the sixth layer may include the same material as the third layer.

While various embodiments have been described with reference to the exemplified drawings, variations and improvements of the disclosed embodiments and other embodiments may be made based on what is described or illustrated in this document.

1. A display device comprising:
a substrate;
a reflective electrode disposed over the substrate and including a first layer, a second layer disposed on the first layer, and a third layer disposed on the second layer;
a first electrode disposed over the reflective electrode;
a common light-emitting layer disposed over the first electrode; and
a second electrode disposed over the common light-emitting layer, wherein the first and second electrodes are structured to supply an electrical signal to the common light-emitting layer to cause emission of light, and
wherein the first layer and the third layer of the reflective electrode include a metal, and the second layer of the reflective electrode includes a metal compound.

2. The display device of claim 1, wherein the first layer includes titanium (Ti), the second layer includes titanium nitride (TiN), and the third layer includes aluminum (Al).

3. The display device of claim 1, wherein a bonding energy between materials of the second layer is higher than a bonding energy between the first layer and the third layer.

4. The display device of claim 1, wherein a thickness of the second layer is less than a thickness of the first layer and a thickness of the third layer.

5. The display device of claim 1, wherein a thickness of the second layer is 0.08 to 0.5 times a thickness of the third layer and 0.2 to 1 times a thickness of the first layer.

6. The display device of claim 1, wherein the substrate includes a first sub-pixel, a second sub-pixel, and a third sub-pixel,
the reflective electrode includes a first reflective electrode on the first sub-pixel, a second reflective electrode on the second sub-pixel, and a third reflective electrode on the third sub-pixel,
a distance between the first reflective electrode and the first electrode in the first sub-pixel is greater than a distance between the second reflective electrode and the first electrode in the second sub-pixel and a distance between the third reflective electrode and the first electrode in the third sub-pixel, and
a distance between the second reflective electrode and the first electrode in the second sub-pixel is greater than a distance between the third reflective electrode and the first electrode in the third sub-pixel.

7. The display device of claim 6, wherein the third reflective electrode is in direct contact with the first electrode.

8. The display device of claim 6, further comprising:
a circuit area disposed between the substrate and the reflective electrode;
a first connecting electrode disposed at a same level as the first reflective electrode;
a second connecting electrode disposed at a same level as the second reflective electrode; and
a third connecting electrode disposed at a same level as the third reflective electrode,
wherein in each sub-pixel, the first connecting electrode is electrically connected to the circuit area, the second connecting electrode is electrically connected to the first connecting electrode, and the third connecting electrode is electrically connected to the second connecting electrode.

9. The display device of claim 8, wherein each of the first connecting electrode, the second connecting electrode, and the third connecting electrode includes a fourth layer including a same material as the first layer, a fifth layer disposed on the fourth layer and including a same material as the second layer, and a sixth layer disposed on the fifth layer and including a same material as the third layer.

10. The display device of claim 9, wherein the fourth layer includes titanium (Ti), the fifth layer includes titanium nitride (TiN), and the sixth layer includes aluminum (Al).

11. The display device of claim 9, wherein a bonding energy between materials constituting the fifth layer is higher than a bonding energy between the fourth layer and the sixth layer.

12. The display device of claim 9, wherein a thickness of the fifth layer is less than a thickness of the fourth layer and a thickness of the sixth layer.

13. The display device of claim 9, wherein a thickness of the fifth layer is 0.08 to 0.5 times a thickness of the sixth layer and 0.2 to 1 times a thickness of the fourth layer.

14. A display device comprising:
a substrate;
a reflective electrode supported by the substrate and first layer, a second layer on the first layer, and a third layer on the second layer;
a first electrode disposed over the reflective electrode;
a common light-emitting layer disposed over the first electrode; and
a second electrode disposed over the common light-emitting layer,
wherein, the reflective electrode is structured such that a conductivity of the third layer is greater than a conductivity of the first layer and a conductivity of the second layer, and the conductivity of the second layer is greater than the conductivity of the first layer, and
a thickness of the second layer is less than a thickness of the first layer and a thickness of the third layer.

15. The display device of claim 14, wherein the first layer and the third layer include a metal, and the second layer includes a metal compound.

16. The display device of claim 14, wherein the first layer includes titanium (Ti), the second layer includes titanium nitride (TiN), and the third layer includes aluminum (Al).

17. The display device of claim 14, wherein a bonding energy between materials of the second layer is higher than a bonding energy between the first layer and the third layer.

18. The display device of claim 14, wherein the thickness of the second layer is 0.08 to 0.5 times the thickness of the third layer and 0.2 to 1 times the thickness of the first layer.

19. The display device of claim 14,
wherein the substrate includes a first sub-pixel, a second sub-pixel, and a third sub-pixel,
wherein the reflective electrode includes a first reflective electrode on the first sub-pixel, a second reflective electrode on the second sub-pixel, and a third reflective electrode on the third sub-pixel.

20. The display device of claim 19, further comprising:
a circuit area disposed between the substrate and the reflective electrode;
a first connecting electrode disposed at a same level as the first reflective electrode;
a second connecting electrode disposed at a same level as the second reflective electrode; and
a third connecting electrode disposed at a same level as the third reflective electrode, and
wherein in each of the first sub-pixel, the second sub-pixel, and the third sub-pixel, the first connecting electrode is electrically connected to the circuit area, the second connecting electrode is electrically connected to the first connecting electrode, and the third connecting electrode is electrically connected to the second connecting electrode,
each of the connecting electrodes includes a fourth layer, a fifth layer on the fourth layer, and a sixth layer on the fifth layer, and
the fourth layer includes a same material as the first layer, the fifth layer includes a same material as the second layer, and the sixth layer includes a same material as the third layer.
